(19) United States
(12) Patent Application Publication
(10) Pub. No.: US 2014/0113230 A1
(43) Pub. Date: Apr. 24, 2014

(54) POSITIVE-TYPE PHOTOSENSITIVE RESIN COMPOSITION AND CURED FILM PREPARED THEREFROM

(71) Applicant: Rohm and Haas Electronic Materials Korea Ltd., Chungcheongnam-do (KR)

(72) Inventors: Eung-Gon KIM, Seoul (KR); Seong-Gi KIM, Gyeonggi-do (KR); Sun RYU, Gyeonggi-do (KR)

(21) Appl. No.: 14/057,959

(22) Filed: Oct. 18, 2013

(30) Foreign Application Priority Data
Oct. 18, 2012 (KR) 10-2012-0115875

(51) Int. Cl. G03F 7/022

(52) U.S. Cl. CPC G03F 7/0226
USPC 430/270.1

(57) ABSTRACT

Disclosed herein is a photosensitive resin composition which comprises (A1) at least one compound selected from the group consisting of a silane compound represented by formula (I), a hydrolyzate thereof and a condensate of the hydrolyzate, (A2) a 1,2-quinonediazide compound, and (A3) an amino-based silane coupling agent represented by formula (II). A cured film prepared from the photosensitive resin composition has an excellent pattern development property, heat resistance and light transmittance, as well as an excellent adhesion property to a silicon nitride(SiNx) substrate, and it can be used as a protective film of an electronic component.

### FIELD OF THE INVENTION

The present invention relates to a positive-type photosensitive resin composition which can exhibit an excellent adhesion property to a silicon nitride (SiNx) substrate, and a cured film prepared from the photosensitive resin composition which can be used as a flattened film for a thin film transistor (TFT) substrate of a liquid crystal display (LCD) or an organic electroluminescence device (OLED), a partition of an OLED, an interlayer dielectric of a semiconductor device, a core or cladding material of an optical waveguide, etc.

### BACKGROUND OF THE INVENTION

For the purpose of preparing a liquid crystal display (LCD) or an organic electroluminescence device (OLED) having higher precision and resolution properties, it has been currently reported a method of raising an aperture ratio thereof (US Patent Publication No. 5953084). In accordance with this method, a transparent flattened film as a protective film is placed on an upper part of a thin film transistor (TFT) substrate, which allows an overlapping of a data line and a pixel electrode, thereby increasing an aperture ratio, as compared to the conventional method.

The flattened film for the TFT substrate of the display is required to have high heat resistance, high transparency and low dielectric constant. In this connection, a combination of phenol-based resins and quinonediazides (Japanese Patent Laid-open Publication No. 1995-98502), a combination of acryl-based resins and quinonediazides (Japanese Patent Laid-open Publication Nos. 1998-153854 and 2001-281853), and the like have been primarily used for the manufacture of such a flattened film. However, these conventional materials have insufficient heat resistance, and therefore, hardened overcoat films prepared therefrom may become undesirably colored by high temperature treatment, thereby deteriorating its transparency.

Meanwhile, a siloxane polymer is well known to have satisfactory properties in terms of heat resistance, transparency and dielectric constant. In order to impart positive-type photosensitivity to the siloxane polymer, US Patent Laid-open Publication No. 2003/211407 disclosed a combination of siloxane polymer and a quinonediazide compound, and Japanese Patent Laid-open Publication No. 1991-59667 disclosed a combination of a siloxane polymer to which a carboxyl group is added by means of a thermal cycloaddition reaction and a quinonediazide compound. These siloxane mixtures, however, are liable to turn white when coated or to turn yellow when thermally cured due to the presence of a quantity of the quinonediazide and/or the carboxyl group in the siloxane polymer. Thus, the siloxane mixtures have some problems in that they cannot be used in the manufacture of a high transparent product and they further exhibit low sensitivity on forming a pattern due to their poor transparency.

Accordingly, it has been suggested an organic siloxane having no carboxyl group. However, the organic siloxane having no carboxyl group still has a problem in that it has poor adhesion to a silicon nitride (SiNₓ) substrate on forming a high resolution micropattern.

### SUMMARY OF THE INVENTION

Accordingly, it is an object of the present invention to provide a positive-type photosensitive resin composition which can exhibit an excellent pattern development property, heat resistance and light transmittance, as well as an excellent adhesion property to a silicon nitride film (SiNx) substrate, and a cured film prepared from the photosensitive resin composition.

In accordance with one aspect of the present invention, there is provided a photosensitive resin composition which comprises:

(A1) at least one compound selected from the group consisting of a silane compound represented by formula (I), a hydrolyzate thereof and a condensate of the hydrolyzate,

(A2) a 1,2-quinonediazide compound, and

(A3) an amino-based silane coupling agent represented by formula (II):

(R)ₚSi(X)₄₋ₚ (I)

wherein R is an unhydrolyzable organic group having 1 to 12 carbon atoms; X is a hydrolyzable group; and p is an integer of 0 to 3.

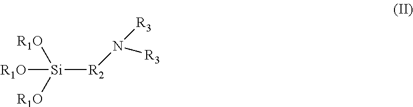

wherein R₂ is a substituted or unsubstituted hydrocarbon group having 1 to 15 carbon atoms, R₂ optionally having at least one hetero atom; and R₁ and R₃ are each independently hydrogen or an organic group having 1 to 12 carbon atoms.

In accordance with another aspect of the present invention, there is provided a cured film prepared from the photosensitive resin composition.

### DETAILED DESCRIPTION OF THE INVENTION

Hereinafter, components of the present invention will be described in detail.

(A1) Silane-Based Compound

The silane-based compound used in the present invention is at least one compound selected from the group consisting of a silane compound represented by formula (I), a hydrolyzate thereof and a condensate of the hydrolyzate. Among them, the hydrolyzate of the silane compound represented by formula (I) or the condensate of the hydrolyzate is preferred:

(R)ₚSi(X)₄₋ₚ (I)

wherein R is an unhydrolyzable organic group having 1 to 12 carbon atoms; X is a hydrolyzable group; and p is an integer of 0 to 3.

Examples of the unhydrolyzable organic group represented by R include an alkyl group having 1 to 12 carbon atoms, an aryl group having 6 to 12 carbon atoms, an arylalkyl group having 7 to 12 carbon atoms and an alkylaryl group having 7 to 12 carbon atoms. They may be linear, branched or cyclic, and may be fused together when a plurality of R exists in the same molecule. R may contain a structural unit having a heteroatom. Examples of the structural unit include ether, ester and sulfide. Unhydrolyzability required for R means the property of being kept stable under a condition that the hydrolyzable group X is hydrolyzed.

The hydrolyzable group represented by X is generally a group capable of forming a silanol group when it is hydrolyzed by heating at room temperature (25° C.) to 100° C. without a catalyst in the presence of excess water, or a group capable of forming a condensate. Examples of the hydrolyzable group include a hydrogen atom, a halogen atom, an alkoxy group having 1 to 12 carbon atoms, an amino group and an acyloxy group having 2 to 12 carbon atoms.

The above p is an integer of 0 to 3, preferably 0 to 2, particularly preferably 1.

The silane compound represented by the above formula (I) is, for example, a silane compound substituted by four hydrolyzable groups, a silane compound substituted by one unhydrolyzable group and three hydrolyzable groups, a silane compound substituted by two unhydrolyzable groups and two hydrolyzable groups, or a silane compound substituted by three unhydrolyzable groups and one hydrolyzable group.

Representative examples of these silane compounds include a silane compound substituted by four hydrolyzable groups such as tetrachlorosilane, tetraaminosilane, tetraacetoxysilane, tetramethoxysilane, tetraethoxysilane, tetrabutoxysilane, tetraphenoxysilane, tetrabenzyloxysilane and tetrapropoxysilane; a silane compound substituted by one unhydrolyzable group and three hydrolyzable groups such as methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d₃-methyltrimethoxysilane, nonafluorobutylethyltrimethoxysilane and trifluoromethyltrimethoxysilane; a silane compound substituted by two unhydrolyzable groups and two hydrolyzable groups such as dimethyldichlorosilane, dimethyldiaminosilane, dimethyldiacetoxysilane, dimethyldimethoxysilane diphenyldimethoxysilane and dibutyldimethoxysilane; and a silane compound substituted by three unhydrolyzable groups and one hydrolyzable group such as trimethylchlorosilane, hexamethyldisilazane, trimethylsilane, tributylsilane, trimethylmethoxysilane and tributylethoxysilane.

Among these examples, the silane compound substituted by one unhydrolyzable group and three hydrolyzable groups is preferred, and methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane and butyltrimethoxysilane are particularly preferred. These silane compounds may be used solely or in combination of two or more.

Preferably, the silane compound used in the present invention may be polysiloxane comprising at least one siloxane unit selected from siloxane units represented by formulae (III), (IV) and (V):

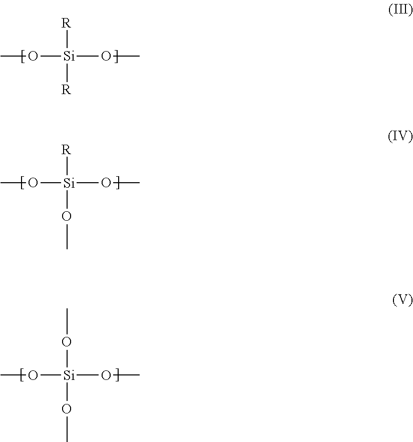

wherein R is each independently hydrogen, C₁-C₁₂ alkyl, C₃-C₁₂ cycloalkyl, C₆-C₁₂ aryl, C₇-C₁₂ alkylaryl or C₇-C₁₂ arylalkyl, preferably, hydrogen, C₁-C₁₂ alkyl or C₆-C₁₂ aryl, more preferably, C₁-C₃ alkyl or C₆-C₁₀ aryl, particularly preferably, methyl, ethyl or phenyl.

More preferably, in consideration of good heat resistance, the silane compound used in the present invention may be polysiloxane comprising the siloxane unit represented by formula (V). The polysiloxane may comprise the siloxane unit represented by formula (V) and siloxane units other than the siloxane unit represented by formula (V) in a molar ratio of 0.05˜0.5 and 0.95˜0.5. In this range, desirable heat-resistance and crack-resistance properties may be obtained.

The weight average molecular weight of the polysiloxane may be in the range of 1,000 to 500,000, preferably 1,000 to 100,000, more preferably 2,000 to 50,000. If the weight average molecular weight of the polysiloxane is at least 1,000, cracks will be formed on the surface of the film when the composition is cured and a desirable thickness may be obtained. Also, if the weight average molecular weight is 500,000 or less, a desirable viscosity of the composition for the coating process may be maintained, thereby improving the surface smoothness.

The amount of the silane compound may be in the range of from 1 to 60 wt %, preferably 5 to 50 wt %, based on the total weight of the photosensitive resin composition exclusive of residual solvents. When the amount of the silane compound falls in the above range, the development property is appropriately controlled, resulting in an enhancement of a residual film formability and a pattern resolution.

(A2) 1,2-quinonediazide Compound (DNQ)

The 1,2-quinonediazide compound used in the present invention may be, for example, any compound used as a photosensitive agent in the photoresist field. Representative examples include an ester of a phenolic compound and 1,2-benzoquinonediazide-4-sulfonic acid or 1,2-benzoquinonediazide-5-sulfonic acid; an ester of a phenolic compound and 1,2-naphthoquinonediazide-4-sulfonic acid or 1,2-naphthoquinonediazide-5-sulfonic acid; a sulfonamide of a phenolic compound having an amino group substituted for a hydroxyl group and 1,2-benzoquinonediazide-4-sulfonic acid or 1,2-benzoquinonediazide-5-sulfonic acid; or a sulfonamide of a phenolic compound having an amino group substituted for a hydroxyl group and 1,2-naphthoquinonediazide-4-sulfonic acid or 1,2-naphthoquinonediazide-5-sulfonic acid. The above compounds may be used as a single compound or in combination of two or more compounds.

Examples of the phenolic compound include 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, and 2,2,4-trimethyl-7,2′,4′-trihydroxyflavane.

Considering to increase the transparency of the positive-type photosensitive resin composition, the 1,2-quinonediazide compound is preferably an ester of 2,3,4-trihydroxybenzophenone and 1,2-naphthoquinonediazide-4-sulfonic acid, an ester of 2,3,4-trihydroxybenzophenone and 1,2-naphthoquinonediazide-5-sulfonic acid, an ester of 4,4′′-[1-[4-[1-[4-hydroxyphenyl]-1-methylethyl]phenyl]ethylidene]bisphenol and 1,2-naphthoquinonediazide-4-sulfonic acid, or an ester of 4,4′-[1-[4-[1-[4 hydroxyphenyl]-1-methylethyl]phenyl]ethylidene]bisphenol and 1,2-naphthoquinonediazide-5-sulfonic acid. The above compounds may be used as a single compound or in combination of two or more compounds.

In particular, an ester of 4,4′-[1-[4-[1-[4hydroxyphenyl]-1-methylethyl]phenyl]ethylidene]bisphenol and 1,2-naphthoquinonediazide-4-sulfonic acid, an ester of 4,4′-[1-[4-[1-[4-hydroxyphenyl]-1-methylethyl]phenyl]ethylidene]bisphenol and 1,2-naphthoquinonediazide-5-sulfonic acid, or a mixture thereof is preferred for transparency. An example of a commercial product thereof includes TPA-520 (Miwon Commercial Co., Ltd.).

The positive-type photosensitive resin composition in accordance with the present invention may comprise the 1,2-quinonediazide compound in an amount ranging from 2 to 50 parts by weight, preferably 5 to 20 parts by weight, based on 100 parts by weight of the solid content of the silane-based compound (A1). When the amount of the 1,2-quinonediazide compound falls in the above range, a pattern can be easily formed; the film derived therefrom does not undergo surface roughening; and the deterioration in the pattern shape such as scum hardly occurs in the bottom portion of the pattern on development.

(A3) Amino-Based Silane Coupling Agent

The amino-based silane coupling agent used in the present invention may be a silane coupling agent having an amino group, represented by formula (II):

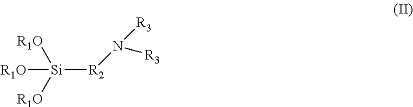

wherein R₂ is a substituted or unsubstituted hydrocarbon group having 1 to 15 carbon atoms, R₂ optionally having at least one hetero atom; and R₁ and R₃ are each independently hydrogen or an organic group having 1 to 12 carbon atoms. The R₁, R₂ and R₃ may be independently linear, branched or circular form.

Examples of the organic groups represented by R₁ or R₃ include C₁-C₁₂ alkyl, C₆-C₁₂ aryl, C₇-C₁₂, arylalkyl or C₇-C₁₂ alkylaryl. When a plurality of R₁ or R₃ exists in the same molecule, they may be fused together.

Representative examples of the amino-based silane coupling agent include 3-aminopropylmethyldi-i-propyloxysilane, 3-aminopropylmethyldiacetoxysilane, 3-aminopropylethyldimethoxysilane, 3-aminopropylethyldiethoxysilane, 3-aminopropylethyldi-n-propyloxysilane, 3-aminopropylethyldi-i-propyloxysilane, 3-aminopropylethyldiacetoxysilane, 3-aminopropylethyldi(methoxyethoxy)silane, 3-aminopropylphenyldimethoxysilane, 3-aminopropylphenyldiethoxysilane, 3-aminopropylphenyldi-n-propyloxysilane, 3-aminopropylphenyldi-i-propyloxysilane, 3-aminopropylphenyldiacetoxysilane, 3-aminopropylphenyldi(methoxyethoxy)silane, N-2-(aminoethyl)-3-aminopropyltrimethoxysilane, N-2-(aminoethyl)-3-aminopropyltriethoxysilane, N-2-(aminoethyl)-3-aminopropyltri-n-propyloxysilane, N-2-(aminoethyl)-3-aminopropyltri-i-propyloxysilane, N-2-(aminoethyl)-3-aminopropyltriacetoxysilane, N-2-(aminoethyl)-3-aminopropyltri(methoxyethoxy)silane, N-2-(aminoethyl)-3-aminopropylmethyldimethoxysilane, N-2-(aminoethyl)-3-aminopropylmethyldiethoxysilane, N-2-(aminoethyl)-3-aminopropylmethyldi-n-propyloxysilane, N-2-(aminoethyl)-3-aminopropylmethyldi-i-propyloxysilane, N-2-(aminoethyl)-3-aminopropylmethyldiacetoxysilane, N-2-(aminoethyl)-3-aminopropylethyldimethoxysilane, N-2-(aminoethyl)-3-aminopropylethyldiethoxysilane, N-2-(aminoethyl)-3-aminopropylethyldi-n-propyloxysilane, N-2-(aminoethyl)-3-aminopropylethyldi-i-propyloxysilane, N-2-(aminoethyl)-3-aminopropylethyldiacetoxysilane, N-2-(aminoethyl)-3-aminopropylethyldi(methoxyethoxy)silane, N-2-(aminoethyl)-3-aminopropylphenyldimethoxysilane, N-2-(aminoethyl)-3-aminopropylphenyldiethoxysilane, N-2-(aminoethyl)-3-aminopropylphenyldi-n-propyloxysilane, N-2-(aminoethyl)-3-aminopropylphenyldi-i-propyloxysilane, N-2-(aminoethyl)-3-aminopropylphenyldiacetoxysilane, N-2-(aminoethyl)-3-aminopropylphenyldi(methoxyethoxy)silane, N-phenyl-3-aminopropyltrimethoxysilane, N-phenyl-3-aminopropyltriethoxysilane, N-phenyl-3-aminopropyltri-n-propyloxysilane, N-phenyl-3-aminopropyltri-i-propyloxysilane, N-phenyl-3-aminopropyltriacetoxysilane, N-phenyl-3-aminopropyltri(methoxyethoxy)silane, N-phenyl-3-aminopropylmethyldimethoxysilane, N-phenyl-3-aminopropylmethyldiethoxysilane, N-phenyl-3-aminopropylmethyldi-n-propyloxysilane, N-phenyl-3-aminopropylmethyldi-i-propyloxysilane, N-phenyl-3-aminopropylmethyldiacetoxysilane, N-phenyl-3-aminopropylethyldimethoxysilane, N-phenyl-3-aminopropylethyldiethoxysilane, N-phenyl-3-aminopropylethyldi-n-propyloxysilane, N-phenyl-3-aminopropylethyldi-i-propyloxysilane, N-phenyl-3-aminopropylethyldiacetoxysilane, N-phenyl-3-aminopropylethyldi(methoxyethoxy)silane, N-phenyl-3-aminopropylphenyldimethoxysilane, N-phenyl-3-aminopropylphenyldiethoxysilane, N-phenyl-3-aminopropylphenyldi-n-propyloxysilane, N-phenyl-3-aminopropylphenyldi-i-propyloxysilane, N-phenyl-3-aminopropylphenyldiacetoxysilane, N-phenyl-3-aminopropylphenyldi(methoxyethoxy)silane, and others. The above compounds may be used as a single compound or in combination of two or more compounds.

The positive-type photosensitive resin composition in accordance with the present invention may comprise the amino-based silane coupling agent in an amount ranging from 0.02 to 20 parts by weight, preferably 0.1 to 10 parts by weight, based on 100 parts by weight of the solid content of the silane-based compound (A1). When the amino-based silane coupling agent is used in the above range, the curing of a film by exposure to light is sufficiently performed, which generates an organic dielectric having improved pattern formation ability and good adhesion to the lower film.

(4) Other Components

The photosensitive resin composition of the present invention may further comprise other components for improving its properties. For instance, said other components may comprise a surfactant and a solvent.

(4-1) Surfactant

The photosensitive resin composition of the present invention may further comprise a surfactant in order to enhance its coatability and to prevent flaw formation, as necessary.

The surfactants are not limited to specific kinds, and preferred are fluorine-based surfactants, silicon-based surfactants, non-ionic surfactants, and the like.

Examples of the surfactants include: fluorine-based and silicon-based surfactants, such as BM-1000, BM-1100 (manufactured by BM CHEMIE Co., Ltd.), Megapack F142 D, Megapack F172, Megapack F173, Megapack F183, F-470, F-471, F-475, F-482, F-489 (manufactured by Dai Nippon Ink Chemical Kogyo Co., Ltd.), Horad FC-135, Horad FC-170 C, Horad FC-430, Horad FC-431 (manufactured by Sumitomo 3M Ltd.), Sufron S-112, Sufron S-113, Sufron S-131, Sufron S-141, Sufron S-145, Sufron S-382, Sufron SC-101, Sufron SC-102, Sufron SC-103, Sufron SC-104, Sufron SC-105, Sufron SC-106 (manufactured by Asahi Glass Co., Ltd.), Eftop EF301, Eftop 303, Eftop 352 (manufactured by Shinakida Kasei Co., Ltd.), SH-28 PA, SH-190, SH-193, SZ-6032, SF-8428, DC-57, DC-190 (manufactured by Toray Silicon Co., Ltd.), DC3PA, DC7PA, SH11PA, SH21PA, SH8400, FZ-2100, FZ-2110, FZ-2122, FZ-2222, FZ-2233 (manufactured by Dow Corning Toray Silicon Co., Ltd.), TSF-4440, TSF-4300, TSF-4445, TSF-4446, TSF-4460, TSF-4452 (manufactured by GE Toshiba Silicon Co., Ltd.), and BYK-333 (manufactured by BYK Co., Ltd.); non-ionic surfactants such as polyoxyethylene alkyl ethers including polyoxyethylene lauryl ether, polyoxyethylene stearyl ether, polyoxyethylene oleyl ether, etc., polyoxyethylene aryl ethers including polyoxyethylene octylphenyl ether, polyoxyethylene nonylphenyl ether, etc., and polyoxyethylene dialkyl esters including polyoxyethylene dilaurate, polyoxyethylene distearate, etc.; and organosiloxane polymer KP341 (manufactured by Shin-Etsu Chemical Co., Ltd.), (meth)acrylate-base copolymer Polyflow No. 57, 95 (Kyoei Yuji Chemical Co., Ltd.), etc. They may be used alone or in a combination of two or more.

The photosensitive resin composition of the present invention may comprise the surfactant in an amount of 0.001 to 5 parts by weight, preferably, 0.05 to 1 part by weight based on 100 parts by weight of solid content of the silane compound (A1). Here, when the amount of the surfactant is 0.001 parts by weight or more, the coatability of the composition is improved and cracks are not formed on the surface of the film coated with the composition. When the amount of the surfactant is 5 parts by weight or less, it has advantage in price.

(4-2) Solvent

The photosensitive resin composition of the present invention may comprise a solvent, especially an organic solvent, in an amount to make its solid content range from 10 to 70% by weight, preferably from 15 to 60% by weight, based on the total weight of the composition. The solid content means the content of components other than solvents contained in the inventive resin composition.

There is no specific limit for the solvents as long as they can dissolve every components of the composition and are chemically stable. At least one solvent selected from propyleneglycol methyl ether acetate, 4-hydroxy-4-methyl-2-pentanone, propyleneglycol methyl ether, ethyl acetoacetate, ethyl acetolactate, ethyl cellosolve-acetate, gamma-butyrolactone, 2-methoxyethyl acetate, ethyl-beta-ethoxypropionate, n-propyl acetate and n-butyl acetate may be used. Preferably, at least one solvent selected from propyleneglycol methyl ether acetate, 4-hydroxy-4-methyl-2-pentanone, propyleneglycol methyl ether and ethyl acetoacetate may be used.

Besides the above components, the composition of the present invention may further comprise, as necessary, other components routinely used for a thermoset resin composition or a photosensitive resin composition.

Further, the present invention provides a cured film prepared from the above photosensitive resin composition.

The cured film may be prepared by a method well-known in the art, for instance, by coating the photosensitive resin composition on a substrate and subjecting it to a curing process. More specifically, the photosensitive resin composition coated on a substrate may be subjected to pre-bake at a temperature of, for instance, 60 to 130° C. to remove the solvent; exposed to light with employing a photomask having a desired pattern; and subjected to development using a developer (e.g., tetramethyl ammonium hydroxide solution (TMAH)) to form a pattern on a coating film. Then, the resulting patterned coating film is subjected to post-bake, as necessary, under a condition, for instance, at a temperature of 150 to 300° C. for 10 minutes to 5 hours to prepare a desired cured film. The light exposure may be carried out at a wavelength ranging from 200 to 450 nm and exposure of 10 to 200 mJ/cm². In accordance with the method of the present invention, a desired pattern can be formed by simple processes.

The cured film of the present invention has an excellent pattern development property, heat resistance and light transmittance, as well as an excellent adhesion property to a silicon nitride (SiNx) substrate. The cured film of the present invention may be used as a flattened film for a thin film transistor TFT) substrate of a liquid crystal display or an organic electroluminescence device (OLED), a partition of an OLED, an interlayer dielectric of a semiconductor device, a core or cladding material of an optical waveguide, etc. Accordingly, the present invention also provides electronic components comprising the cured film as a protective film.

Hereinafter, the present invention will be described in more detail with reference to the following Examples. However, these Examples are set forth to illustrate the present invention, and the scope of the present invention is not limited thereto.

In the following Examples, the weight-average molecular weight is determined by means of gel permeation chromatography (GPC) using polystyrene standards.

### PREPARATION EXAMPLE 1

### Preparation of Polysiloxane (A1)

0.07 g (0.0019 mol) of 0.1N hydrochloric acid and 40.57 g (2.25 mol) of deionized water were added to a reaction flask, followed by stirring. Then, 92.45 g (0.383 mol) of phenyltriethoxysilane (Aldrich), 40.06 g (0.192 mol) of tetraethoxysilane (Aldrich), 34.29 g (0.192 mol) of methyltriethoxysilane (Aldrich) and 12 g of propylene glycol methyl ether acetate (Aldrich) were added thereto, followed by stirring at room temperature for an hour. The reaction mixture was distilled at 105° C. for 2 hours and was then subjected to a reaction at 100° C. for 3 hours. After the reaction was completed, 6 g of propylene glycol methyl ether acetate was added to the reaction mixture and then cooled. The acid remained in the reaction mixture was removed by using an ion exchange column The resulting mixture was added to a reactor, and then water and the alcohols were removed therefrom at 45° C. under a reduced pressure to obtain a polysiloxane. The polysiloxane had a weight-average molecular weight (Mw) of about 4000.

### EXAMPLE 1

100 parts by weight as a solid content of the polysiloxane obtained in Preparation Example 1, 20 parts by weight of TPA-520 (Miwon Commercial Co., Ltd.) as an 1,2-quinone diazide compound, 1 part by weight of GSCA-001 (Genenchip Co., Ltd.) as an amino-based silane coupling agent, and 0.2 parts by weight of BYK-333 (a leveling surfactant, BYK) as a silicone-based surfactant were mixed homogeneously in propylene glycol methyl ether acetate as an organic solvent to obtain a resin composition as a liquid having a solid content of 35% by weight, which was then filtered by using a membrane filter having a pore size of 0.2 μm.

### EXAMPLE 2

The procedure of Example 1 was repeated except that 1 part by weight of Z-6011 (Toray Dow Corning Silicone Co., Ltd.) was used as an amino-based silane coupling agent instead of GSCA-001 to obtain a resin composition.

### EXAMPLE 3

The procedure of Example 1 was repeated except that 1 part by weight of Z-6020 (Toray Dow Corning Silicone Co., Ltd.) was used as an amino-based silane coupling agent instead of GSCA-001 to obtain a resin composition.

### COMPARATIVE EXAMPLE 1

The procedure of Example 1 was repeated except that no amino-based silane coupling agent was used to obtain a resin composition.

### COMPARATIVE EXAMPLE 2

The procedure of Example 1 was repeated except that 1 part by weight of GPTMS (γ-glycidoxypropyltrimethoxysilane, Aldrich), a silane coupling agent having no amino group, was used instead of GSCA-001 to obtain a resin composition.

### COMPARATIVE EXAMPLE 3

The procedure of Example 1 was repeated except that 1 part by weight of KBE 9007 (γ-isocyanatopropyltriethoxysilane, Shin-Etsu Chemical Co., Ltd.), a silane coupling agent having no amino group, was used instead of GSCA-001 to obtain a resin composition.

The cured films prepared by using the resin compositions obtained in Examples 1 to 3 and Comparative Examples 1 to 3 were tested in order to evaluate their development property, adhesion of the linear micropattern, transmittance and film retention rate according to the following methods. The results are shown in Table 1 below.

1. Evaluation of Development Property

The photosensitive resin composition was applied onto a silicon nitride substrate by spin coating, pre-baked and dried on a hot plate kept at 110° C. for 90 seconds to form a coating film having a thickness of 4.4 μm. The coating film was exposed, through a mask having a pattern consisting of square holes with sizes ranging from 1 μm to 15 μm at intervals of 1 μm, to light at an exposure rate of about 40 mJ/cm² based on a wavelength of 365 nm using an aligner (MA6™), which emits light having a wavelength of 200 to 450 nm. The film was then developed by spraying a developing agent, which was an aqueous solution of 2.38% tetramethylammonium hydroxide, through a nozzle at 25° C. The exposed film was heated in a convection oven at 200° C. for 30 minutes to obtain a heat-cured film. The development property of the cured film was evaluated based on the shape of the developed micropattern.

The shape of the developed micropattern was evaluated based on the following standards by observing the pattern formed in contact holes having a line width of 10 μm in the cured film with a scanning electron microscope.

⊚: The shape of rectangle was clear, and no bottom tail was observed.

Δ: The shape of rectangle was clear, but the surface of the cured film was not smooth or a spotted residual film was formed.

×: The shape of rectangle was not clear, or the cured film was not developed.

2. Evaluation of Light Transmittance

The procedures same as in the above evaluation of a pattern development property were repeated except that the photosensitive resin composition was applied onto a glass substrate by spin coating, to prepare a heat-cured film having a thickness of about 4 μm. The light transmittance in a wavelength ranging from 400 to 800 nm of the heat-cured film was measured using an ultraviolet ray/visible ray spectrophotometer.

3. Evaluation of Adhesion of Linear Micropattern

The procedures same as in the above evaluation of a pattern development property were repeated except that a mask having an 1:1 line pattern (line and space pattern) with sizes ranging from 1 μm to 10 μm at intervals of 1 μm was applied to the film, to prepare a heat-cured film. The line and space pattern of the heat-cured film was observed and the adhesion of the formed linear micropattern was evaluated in accordance with the standards as shown below.

⊚: 2-6 μm linear micropattern was not peeled off after developed, and the surface thereof remained soft.

Δ: 2-6 μm linear micropattern was not peeled off after developed, but the surface thereof remained rough or was partly torn out.

×: 2-6 μm linear micropattern was peeled off after developed, and consequently, the desired pattern was not formed.

4. Evaluation of Film Retention Rate _o The thickness of the heat-cured film (after developed and heat-cured, i.e., after post-bake) was measured using a contact film thickness measuring apparatus(Surface-profiler, trade name: ALPHA-STEP IQ), as compared to the initial thickness, 4.4 μm, thereof (after pre-bake). The film retention rate of the heat-cured film was expressed as a percentage(%).

TABLE 1

| | Pattern | Adhesion of | Light | Film |
|---|---|---|---|---|
| | development | linear | transmittance | retention |
| | property | micropattern | (%)(400~800 nm) | rate (%) |
| Example 1 | ⊚ | ⊚ | 99 | 93 |
| Example 2 | ⊚ | ⊚ | 99 | 93 |
| Example 3 | ⊚ | ⊚ | 99 | 93 |
| Comp. Ex. 1 | ⊚ | X | 99 | 92 |
| Comp. Ex. 2 | ⊚ | X | 99 | 92 |
| Comp. Ex. 3 | ⊚ | X | 99 | 93 |

As seen from the results of Table 1, the resin compositions comprising an amino-based silane coupling agent prepared in Examples 1 to 3 provided cured films having an excellent pattern development property, light transmittance and film retention rate, as well as an excellent adhesion property to a silicon nitride substrate, as compared to those comprising no silane coupling agent or comprising a silane coupling agent with no amino group prepared in Comparative Examples 1 to 3.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A photosensitive resin composition which comprises:
(A1) at least one compound selected from the group consisting of a silane compound represented by formula (I), a hydrolyzate thereof and a condensate of the hydrolyzate,
(A2) a 1,2-quinonediazide compound, and
(A3) an amino-based silane coupling agent represented by formula (II):
(R)ₚSi(X)₄₋ₚ (I)
wherein R is an unhydrolyzable organic group having 1 to 12 carbon atoms; X is a hydrolyzable group; and p is an integer of 0 to 3. 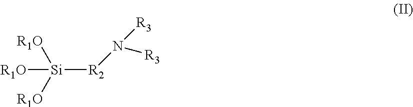
wherein R₂ is a substituted or unsubstituted hydrocarbon group having 1 to 15 carbon atoms, R₂ optionally having at least one hetero atom; and R₁ and R₃ are each independently hydrogen or an organic group having 1 to 12 carbon atoms.

2. The composition of claim 1, wherein the component (A1) is a polysiloxane comprising at least one siloxane unit selected from siloxane units represented by formulae (III), (IV) and (V): 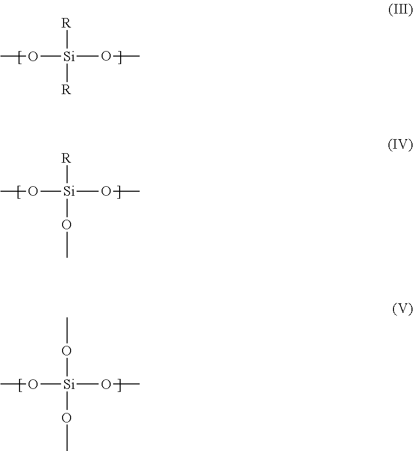
wherein R is each independently hydrogen, C₁-C₁₂ alkyl, C₃-C₁₂ cycloalkyl, C₆-C₁₂ aryl, C₇-C₁₂ alkylaryl, or C₇-C₁₂ arylalkyl.

3. The composition of claim 2, wherein the component (A1) comprises the siloxane unit represented by formula (V) and siloxane units other than the siloxane unit represented by formula (V) in a molar ratio of 0.05˜0.5 and 0.95˜0.5.

4. The composition of claim 1, wherein the 1,2-quinonediazide compound is an ester of 4,4′-[1-[4-[1-[4-hydroxyphenyl]-1-methylethyl]phenyl]ethylidene]bisphenol and 1,2-naphthoquinonediazide-4-sulphonic acid, an ester of 4,4′-[1-[4-[1-[4 hydroxyphenyl]-1-methylethyl]phenyl]ethylidene]bisphenol and 1,2-naphthoquinonediazide-5-sulphonic acid, or a mixture thereof.

5. The composition of claim 1, which comprises the 1,2-quinonediazide compound and the amino-based silane coupling agent in amounts ranging from 2 to 50 parts by weight and 0.02 to 20 parts by weight, respectively, based on 100 parts by weight of the solid content of the component (A1).
